(19) United States
(12) Patent Application Publication
(10) Pub. No.: US 2013/0139023 A1
(43) Pub. Date: May 30, 2013

(54) Variable Sector Size Interleaver

(71) Applicants: Yang Han, Sunnyvale, CA (US); Zongwang Li, Santa Clara, CA (US); Shaohua Yang, San Jose, CA (US)

(72) Inventors: Yang Han, Sunnyvale, CA (US); Zongwang Li, Santa Clara, CA (US); Shaohua Yang, San Jose, CA (US)

(73) Assignee: LSI Corporation

(21) Appl. No.: 13/305,551

(22) Filed: Nov. 28, 2011

(51) Int. Cl. G06F 12/06; G06F 11/10; H03M 13/05

(52) U.S. Cl. 714/752; 711/157; 711/E12.079; 714/E11.032

(57) ABSTRACT

Various embodiments of the present invention are related to methods and apparatuses for interleaving data, and more particularly to methods and apparatuses for interleaving variably sized blocks of data. For example, in one embodiment an apparatus includes a data partitioner operable to partition the block of data into a real data portion and a missing bits portion. The real data portion is adapted to contain data bits from the variably sized block of data and the missing bits portion is adapted to be filled with a variable number of the data bits. The apparatus also includes at least one local interleaver operable to apply a permutation across each of a plurality of sub-portions of the real data portion and the missing bits portion, and a global interleaver operable to apply a global permutation across the real data portion.

### BACKGROUND

Various data transfer systems have been developed including storage systems, cellular telephone systems, and radio transmission systems. In each of the systems data is transferred from a sender to a receiver via some medium. For example, in a storage system, data is sent from a sender (i.e., a write function) to a receiver (i.e., a read function) via a storage medium. As information is stored and transmitted in the form of digital data, errors are introduced that, if not corrected, can corrupt the data and render the information unusable. The effectiveness of any transfer is impacted by any losses in data caused by various factors. Many types of error checking systems have been developed to detect and correct errors in digital data. For example, in perhaps the simplest system, a parity bit can be added to a group of data bits, ensuring that the group of data bits (including the parity bit) has either an even or odd number of ones. When using odd parity, as the data is prepared for storage or transmission, the number of data bits in the group that are set to one are counted, and if there is an even number of ones in the group, the parity bit is set to one to ensure that the group has an odd number of ones. If there is an odd number of ones in the group, the parity bit is set to zero to ensure that the group has an odd number of ones. After the data is retrieved from storage or received from transmission, the parity can again be checked, and if the group has an even parity, at least one error has been introduced in the data. At this simplistic level, some errors can be detected but not corrected.

The parity bit may also be used in error correction systems, including in low density parity check (LDPC) decoders. An LDPC code is a parity-based code that can be visually represented in a Tanner graph 100 as illustrated in FIG. 1. In an LDPC decoder, multiple parity checks are performed in a number of check nodes 102, 104, 106 and 108 for a group of variable nodes 110, 112, 114, 116, 118, 120, 122, and 124. The connections (or edges) between variable nodes 110-124 and check nodes 102-108 are selected as the LDPC code is designed, balancing the strength of the code against the complexity of the decoder required to execute the LDPC code as data is obtained. The number and placement of parity bits in the group are selected as the LDPC code is designed. Messages are passed between connected variable nodes 110-124 and check nodes 102-108 in an iterative process, passing beliefs about the values that should appear in variable nodes 110-124 to connected check nodes 102-108. Parity checks are performed in the check nodes 102-108 based on the messages and the results are returned to connected variable nodes 110-124 to update the beliefs if necessary. LDPC decoders may be implemented in binary or non-binary fashion. In a binary LDPC decoder, variable nodes 110-124 contain scalar values based on a group of data and parity bits that are retrieved from a storage device, received by a transmission system or obtained in some other way. Messages in the binary LDPC decoders are scalar values transmitted as plain-likelihood probability values or log-likelihood-ratio (LLR) values representing the probability that the sending variable node contains a particular value. In a non-binary LDPC decoder, variable nodes 110-124 contain symbols from a Galois Field, a finite field GF(p^{k}) that contains a finite number of elements, characterized by size p^{k} where p is a prime number and k is a positive integer. Messages in the non-binary LDPC decoders are multi-dimensional vectors, generally either plain-likelihood probability vectors or LLR vectors.

The connections between variable nodes 110-124 and check nodes 102-108 may be presented in matrix form as follows, where columns represent variable nodes, rows represent check nodes, and a random non-zero element a(i,j) from the Galois Field at the intersection of a variable node column and a check node row indicates a connection between that variable node and check node and provides a permutation for messages between that variable node and check node:

$$H = [ \begin{matrix}a ( 1 , 1 ) & 0 & 0 & a ( 1 , 2 ) & 0 & a ( 1 , 3 ) & a ( 1 , 4 ) & 0 \\ 0 & a ( 2 , 1 ) & 0 & 0 & a ( 2 , 2 ) & 0 & 0 & a ( 2 , 3 ) \\ a ( 3 , 1 ) & 0 & a ( 3 , 2 ) & 0 & a ( 3 , 3 ) & a ( 3 , 4 ) & 0 & a ( 3 , 5 ) \\ 0 & a ( 4 , 1 ) & 0 & a ( 4 , 2 ) & 0 & 0 & a ( 4 , 3 ) & a ( 4 , 4 )\end{matrix} ]$$

By providing multiple check nodes 102-108 for the group of variable nodes 110-124, redundancy in error checking is provided, enabling errors to be corrected as well as detected. Each check node 102-108 performs a parity check on bits or symbols passed as messages from its neighboring (or connected) variable nodes. In the example LDPC code corresponding to the Tanner graph 100 of FIG. 1, check node 102 checks the parity of variable nodes 110, 116, 120 and 122. Values are passed back and forth between connected variable nodes 110-124 and check nodes 102-108 in an iterative process until the LDPC code converges on a value for the group of data and parity bits in the variable nodes 110-124. For example, variable node 110 passes messages to check nodes 102 and 106. Check node 102 passes messages back to variable nodes 110, 116, 120 and 122. The messages between variable nodes 110-124 and check nodes 102-108 are probabilities or beliefs, thus the LDPC decoding algorithm is also referred to as a belief propagation algorithm. Each message from a node represents the probability that a bit or symbol has a certain value based on the current value of the node and on previous messages to the node.

A message from a variable node to any particular neighboring check node is computed using any of a number of algorithms based on the current value of the variable node and the last messages to the variable node from neighboring check nodes, except that the last message from that particular check node is omitted from the calculation to prevent positive feedback. Similarly, a message from a check node to any particular neighboring variable node is computed based on the current value of the check node and the last messages to the check node from neighboring variable nodes, except that the last message from that particular variable node is omitted from the calculation to prevent positive feedback. As iterations are performed in the system, messages pass back and forth between variable nodes 110-124 and check nodes 102-108, with the values in the nodes 102-124 being adjusted based on the messages that are passed, until the values converge and stop changing or until processing is halted.

Data is typically processed by LDPC encoders and decoders in a fixed block size, with the associated H matrix adapted to this block size. When the amount of user data to be processed by an LDPC encoder and decoder is variable, the LDPC decoder still operates on the fixed block size, even if the data block processed by the LDPC decoder is not filled with data. In other words, the LDPC decoder always decodes on the full H matrix even if some of the associated data bits are not provided to the LDPC decoder. The LDPC decoder is designed with an H matrix based on the largest sector size, and decodes on the full H matrix even when operating on a smaller sector, so that some of the bits for the H matrix are not transmitted through the channel to the LDPC decoder.

An interleaver may be used to prepare data for decoding in an LDPC encoder, which is particularly sensitive to burst errors which concentrate errors in a localized run of data. The interleaver spreads burst errors across the block of data, making it appear more like random data, which the LDPC is better adapted to correct.

A need remains for more efficient and accurate error correction techniques for variably sized blocks of data.

### BRIEF SUMMARY

Various embodiments of the present invention are related to methods and apparatuses for interleaving data, and more particularly to methods and apparatuses for interleaving variably sized blocks of data. For example, in one embodiment an apparatus for interleaving a variably sized block of data includes a data partitioner operable to partition the block of data into a real data portion and a missing bits portion. The real data portion is adapted to contain data bits from the variably sized block of data and the missing bits portion is adapted to be filled with a variable number of the data bits. The apparatus also includes at least one local interleaver operable to apply a permutation across each of a plurality of sub-portions of the real data portion and the missing bits portion, and a global interleaver operable to apply a global permutation across the real data portion. By grouping missing bits in the interleaved data, some or all of the missing bits can be omitted from downstream processing. For example, in some embodiments missing bits are grouped in circulants for an H matrix in a downstream LDPC decoder by the interleaver, enabling the LDPC decoder to skip decoding of the circulants containing no data bits.

This summary provides only a general outline of some embodiments according to the present invention. Many other objects, features, advantages and other embodiments of the present invention will become more fully apparent from the following, detailed description, the appended claims and the accompanying drawings.

### BRIEF DESCRIPTION OF THE DRAWINGS

A further understanding of the various embodiments of the present invention may be realized by reference to the figures which are described in remaining portions of the specification. In the figures, like reference numerals may be used throughout several drawings to refer to similar components. In the figures, like reference numerals are used throughout several figures to refer to similar components. In some instances, a sub-label consisting of a lower case letter is associated with a reference numeral to denote one of multiple similar components. When reference is made to a reference numeral without specification to an existing sub-label, it is intended to refer to all such multiple similar components.

FIG. 1 depicts a Tanner graph of an example prior art LDPC code;

FIG. 2 depicts a block diagram of a read channel which may be used to retrieve or receive stored or transmitted data in accordance with various embodiments of the present invention;

FIG. 3 depicts a diagram illustrating interleaving of data between a detector domain and a decoder domain in accordance with various embodiments of the present invention;

FIG. 4 depicts the concentration of missing bits by a variable sector size interleaver in circulant sub-matrices at the end of an H matrix for a non-layer variable sector size LDPC decoder in accordance with various embodiments of the present invention;

FIG. 5 depicts the concentration of missing bits by a variable sector size interleaver in circulant sub-matrices at the end of two halves of an H matrix for a variable sector size LDPC layer decoder in accordance with various embodiments of the present invention;

FIG. 6 depicts a variable sector size interleaver in accordance with various embodiments of the present invention;

FIG. 7 depicts a flow diagram showing a method for variable sector size interleaving in accordance with various embodiments of the present invention;

FIG. 8 depicts a storage system including a variable sector size interleaver in accordance with some embodiments of the present invention;

FIG. 9 depicts a virtual storage system including a variable sector size interleaver ill accordance with some embodiments of the present invention; and

FIG. 10 depicts an example data transmission device including a variable sector size interleaver in accordance with some embodiments of the present invention.

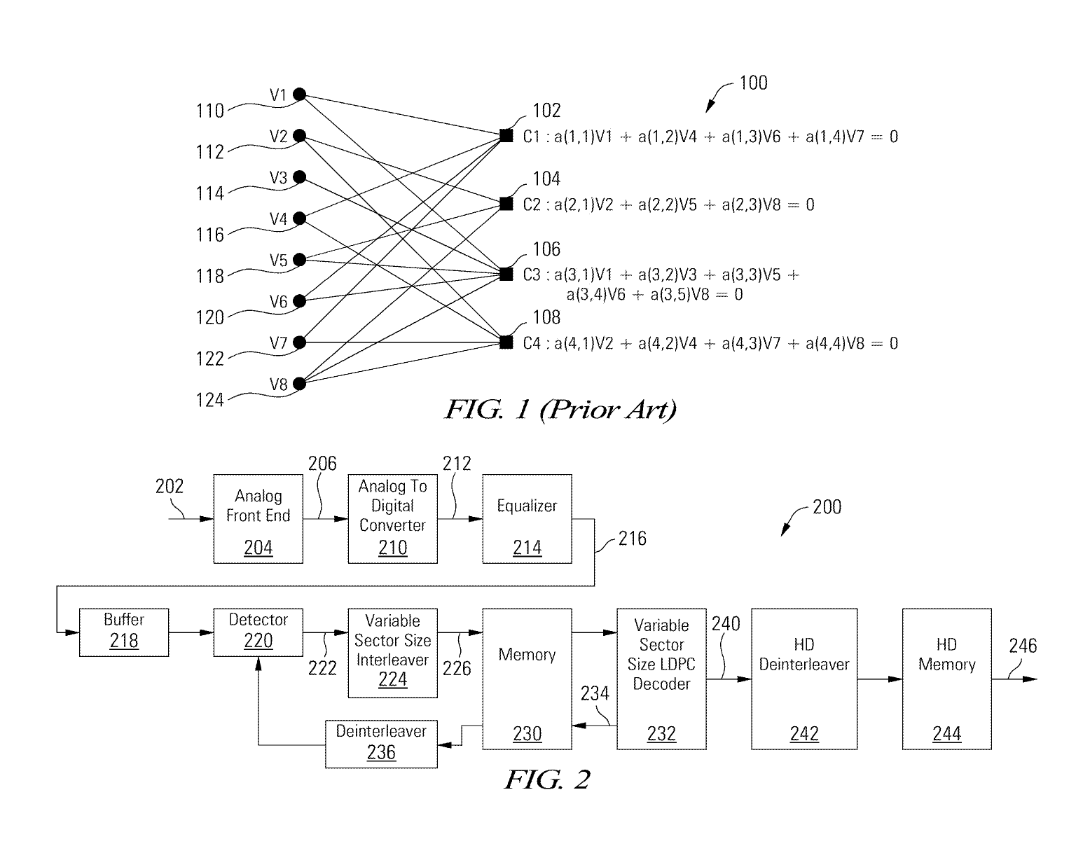

### DETAILED DESCRIPTION OF THE INVENTION

Various embodiments of the present invention are related to methods and apparatuses for interleaving data, and more particularly to methods and apparatuses for interleaving variably sized blocks of data. The variable sector size interleaver disclosed herein permutes a block of incoming data, shuffling the data bits across the block so that burst errors are distributed across the block rather than being grouped in a burst. (The variable sector size interleaver is also referred to herein simply as an interleaver for brevity.) This allows a downstream error correction circuit such as an LDPC decoder to better correct the distributed errors. Although detailed example embodiments of an interleaver disclosed herein are operable to receive data from a detector and provide data to a LDPC decoder, the interleaver may be used for other applications with a variety of different data sources and destinations.

The interleaver is operable to accept an input data block of variable size, for example from a sector of user data on a magnetic hard disk drive, and to yield an output having a size adapted to a downstream component such as an LDPC decoder. When the input data block is smaller than the data block size expected by the downstream component, the interleaver positions the missing bits in the output data block in a manner that enables the downstream component to exclude some or all of the missing bits from further processing. The interleaver may also fill some or all of the missing bits with placeholder data in case the downstream component does process some or all of the missing bits. Furthermore, the interleaver may either transfer the missing bits to the LDPC decoder along with user hits, or may omit some or all of the missing bits when transferring data to the LDPC decoder.

In some embodiments, the interleaver prepares output data blocks to be decoded in an LDPC decoder, whether binary or non-binary, layered or non-layered. The LDPC decoder may use, but is not limited to, quasi-cyclic LDPC codes in which the parity check H matrix is an array of circulant sub-matrices, cyclically shifted versions of identity matrices and null matrices with different cyclical shifts. The interleaver groups the missing bits in sub-matrix circulants that can be omitted from decoding iterations in the LDPC decoder.

When the LDPC decoder receives less than the full amount of data for which the H matrix was designed, and the data is prepared by the variable sector size interleaver, decoding performance is improved by skipping processing of circulant sub-matrices that do not contain user data, also referred to herein as partial updating. The data provided to the LDPC decoder by the variable sector size interleaver is consolidated by circulants so that missing bits are efficiently grouped in circulants, which can then be omitted from local decoding iterations.

User data is defined herein as data to be decoded by the LDPC decoder and for which parity bits have been provided, for example from an LDPC encoder. The term “user data” does not imply any particular source of the data to be decoded. In some embodiments, user data is data read from a magnetic storage medium and excludes sync marks, preambles, and other formatting data.

By skipping processing of circulants that do not contain user data, the LDPC decoder uses less time to perform a local decoding iteration on the H matrix. Variable nodes and check nodes relating to the missing bit positions do not need to be iteratively updated during partial updating. By reducing the processing time for one local iteration, more local and global iterations can be performed in a given time, thus improving performance.

Circulants that are partially empty, which contain some user data but are not filled completely with user data, are included in the local decoding iteration and processed in the LDPC decoder. The interleaver fills empty portions of these circulants, for example, with zero values, and the corresponding LLR values are set, for example, to the maximum reliability levels. For example, in an LDPC decoder with four-bit LLR values assigning likelihoods from 0 to 15, the LLR values for the fill-in zero values is set in some embodiments to 15. Circulants are referred to herein as empty herein when they contain no user data, even if they are filled with zeros, and as partially empty when they contain some user data but are not full of user data, even when the portion of the circulant not containing user data is filled with zeros.

The possibility of decoding errors is also reduced by grouping missing bits in the interleaver and omitting processing in the LDPC decoder. When zero-filled missing bit positions in the H matrix are decoded, even with their initial values and corresponding LLR values set to predetermined levels, they may introduce decoding errors due to the influence of wrong variable node messages with lower reliability on bits or symbols with high reliability. This may even prevent decoding, convergence by reliability oscillation, in which LLR values oscillate and delay or prevent convergence. By omitting empty circulants from local decoding iterations, the possibility of decoding errors and convergence failure is reduced.

Although the variable sector size interleaver disclosed herein is not limited to any particular application, several examples of applications are presented herein that benefit from embodiments of the present invention. Turning to FIG. 2, a read channel 200 is used to process an analog signal 202 and to retrieve user data bits from the analog signal 202 without errors. In some cases, analog signal 202 is derived from a read/write head assembly in a magnetic storage medium. In other cases, analog signal 202 is derived from a receiver circuit that is operable to receive a signal from a transmission medium. The transmission medium may be wireless or wired such as, but not limited to, cable or optical connectivity. Based upon the disclosure provided herein, one of ordinary skill in the art will recognize a variety of sources from which analog signal 202 may be derived.

The read channel 200 includes an analog front end 204 that receives and processes the analog signal 202. Analog front end 204 may include, but is not limited to, an analog filter and an amplifier circuit as are known in the art. Based upon the disclosure provided herein, one of ordinary skill in the art will recognize a variety of circuitry that may be included as part of analog front end 204. In some cases, the gain of a variable gain amplifier included as part of analog front end 204 may be modifiable, and the cutoff frequency and boost of an analog filter included in analog front end 204 may be modifiable. Analog front end 204 receives and processes the analog signal 202, and provides a processed analog signal 206 to an analog to digital converter 210.

Analog to digital converter 210 converts processed analog signal 206 into a corresponding series of digital samples 212. Analog to digital converter 210 may be any circuit known in the art that is capable of producing digital samples corresponding to an analog input signal. Based upon the disclosure provided herein, one of ordinary skill in the art will recognize a variety of analog to digital converter circuits that may be used in relation to different embodiments of the present invention. Digital samples 212 are provided to an equalizer 214. Equalizer 214 applies an equalization algorithm to digital samples 212 to yield an equalized output 216. In some embodiments of the present invention, equalizer 214 is a digital finite impulse response filter circuit as is known in the art. Data or codewords contained in equalized output 216 may be stored in a buffer 218 until a data detector 220 is available for processing.

The data detector 220 performs a data detection process on the received input, resulting in a detected output 222. In some embodiments of the present invention, data detector 220 is a Viterbi algorithm data detector circuit, or more particularly in some cases, a maximum a posteriori (MAP) data detector circuit as is known in the art. In these embodiments, the detected output 222 contains log-likelihood-ratio (LLR) information about the likelihood that each bit or symbol has a particular value. Based upon the disclosure provided herein, one of ordinary skill in the art will recognize a variety of data detectors that may be used in relation to different embodiments of the present invention. Data detector 220 is started based upon availability of a data set in buffer 218 from equalizer 214 or another source.

The detected output 222 from data detector 220 is provided to a variable sector size interleaver 224 that protects data against burst errors. Burst errors overwrite localized groups or bunches of bits. Because LDPC decoders are best suited to correcting errors that are more uniformly distributed, burst errors can overwhelm LDPC decoders. The interleaver 224 prevents this by interleaving or shuffling the detected output 222 from data detector 220 to yield an interleaved output 226 which is stored in a memory 230. The interleaved output 226 from the memory 230 is provided to an LDPC decoder 232 which performs parity checks on the interleaved output 226, ensuring that parity constraints established by an LDPC encoder (not shown) before storage or transmission are satisfied in order to detect and correct any errors that may have occurred in the data during storage or transmission or during processing by other components of the read channel 200.

Multiple detection and decoding iterations may be performed in the read channel 200, referred to herein as global iterations. (In contrast, local iterations are decoding iterations performed within the LDPC decoder 232.) To perform a global iteration, LLR values 234 from the LDPC decoder 232 are stored in memory 230, deinterleaved in a deinterleaver 236 to reverse the process applied by interleaver 224, and provided again to the data detector 220 to allow the data detector 220 to repeat the data detection process, aided by the LLR values 234 from the LDPC decoder 232. In this manner, the read channel 200 can perform multiple global iterations, allowing the data detector 220 and LDPC decoder 232 to converge on the correct data values.

The LDPC decoder 232 also produces hard decisions 240 about the values of the data bits or symbols contained in the interleaved output 226 of the interleaver 224. For binary data bits, the hard decisions may be represented as 0's and 1's. For non-binary or multi-level symbols, in a GF(4) LDPC decoder, the hard decisions may be represented by field elements 00, 01, 10 and 11.

The hard decisions 240 from LDPC decoder 232 are deinterleaved in a hard decision deinterleaver 242, reversing the process applied in interleaver 224, and stored in a hard decision memory 244 before being provided to a user or further processed. For example, the output 246 of the read channel 200 may be further processed to reverse formatting changes applied before storing data in a magnetic storage medium or transmitting the data across a transmission channel.

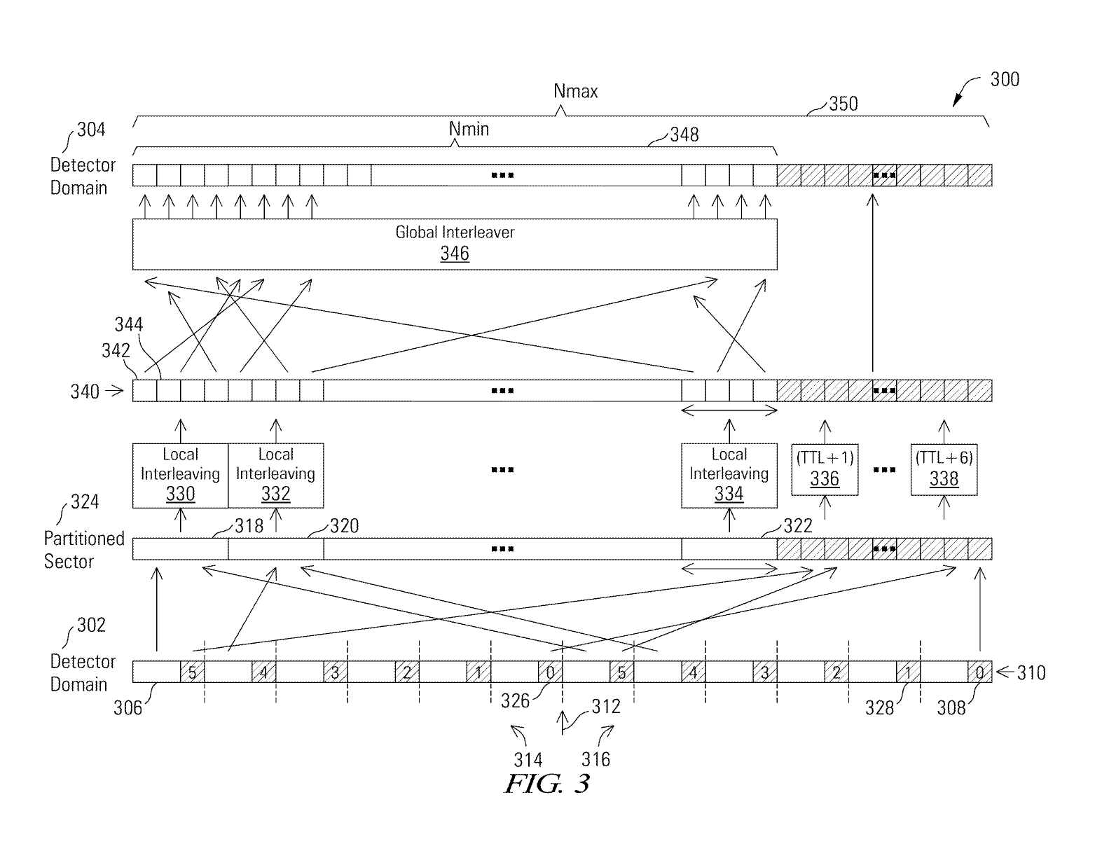

Turning now to FIG. 3, a diagram 300 illustrates interleaving of data by a variable sector size interleaver between a detector domain 302 (e.g., detected output 222 from data detector 220) and a decoder domain 304 (e.g., interleaved output 226 for LDPC decoder 232) in accordance with various embodiments of the present invention. The diagram 300 illustrates the placement of real data and missing bits in an entire block or sector to be interleaved and decoded or otherwise processed (also referred to as a component codeword for an LDPC decoder). In various embodiments, the term real data may include both user data and parity bits, or just user data, based on the particular design of the interleaver and the downstream component or components. For example, in some embodiments, parity bits for an LDPC decoder may be separated from user data and interleaved separately before providing them to the LDPC decoder. In the diagram 300, real data is represented by clear blocks (e.g., 306) and groups of missing bits are represented by crosshatched blocks (e.g., 308). The data bit index increases from left to right in the diagram 300. The diagram 300 is not drawn to scale.

The variable sector size interleaver may be adapted to process a discrete number of different incoming block sizes with predetermined granular size differences, or may be adapted to process blocks with continuously variable size differences. In some embodiments, the interleaver is adapted to prepare data for decoding in an LDPC decoder, with a possibility of up to 6 out of 55 total circulants in a sector having missing data, and the amount of missing data varying continuously from no missing data to 6 circulants being completely empty, as illustrated in Table 1, where the circulant size is denoted as X:

TABLE 1

| | | | Decoder H |
|---|---|---|---|
| LDPC Encoded | Missing Bit | Missing Full | Matrix Size |
| Length (CCW) | Length | Circulants | (Circulants) |
| 54X + 1 to 55X | 0 to (X − 1) | 0 | 55 |
| (Nmax) | | | |
| 53X + 1 to 54X | X to 2X − 1 | 1 | 54 |
| 52X + 1 to 53X | 2X to 3X − 1 | 2 | 53 |
| 51X + 1 to 52X | 3X to 4X − 1 | 3 | 52 |
| 50X + 1 to 51X | 4X to 5X − 1 | 4 | 51 |
| 49X + 1 to 50X | 5X to 6X − 1 | 5 | 50 |
| 49X(Nmin) | 6X | 6 | 49 |

The first column indicates the number of user data bit. The first column indicates the number of encoded data bits, including user data and parity bits. The second column indicates the number of missing bits. The third column indicates the number of circulants completely void of real data. The fourth column indicates the number of circulants to be processed in the LDPC decoder which contain at least some real data. Notably, the LDPC decoder may be designed with a fixed H matrix size, but adapted to omit circulants which are completely void of real data from decoding iterations, effectively changing the H matrix size to be decoded. Thus, the missing data may vary in a continuous fashion from no missing bits all the way up to 6 circulants missing data bits, and the variable sector size interleaver groups the missing bits by circulants so that the LDPC decoder can omit them from decoding iterations.

The bottom row of the diagram 300 illustrates data in the detector domain 302 received by the interleaver to be interleaved. In the detector domain 302, missing bits are scattered across the sector at the end of each of 12 user samples 310 (indicated by dashed dividing lines) from a detector. In this example embodiment, each of the 12 user samples 310 from the detector contains up to 440 bits of real data, of which up to 48 may be missing hits. Thus, a user sample 310 may contain 440 bits of real data and no missing bits or 392 bits or real data and 48 missing bits or anywhere between.

The interleaver partitions the sector, moving real data to the left in the second row and missing bits to the end of the sector. In some embodiments, the interleaver partitions the real data based on a center dividing line 312, grouping chunks of data from the first half 314 of the sector with chunks from the second half 316 of the sector to form X-bit long segments (e.g., 318, 320, up to 322) in the partitioned sector 324, where X is the length of a circulant. The missing bits are regressively filled in from right to left in the partitioned sector 324, in increasing order of label (0, 1, 2, 3, 4, 5), with the second half followed by the first half. For example, the ‘0’ block of missing bits 308 from the second half 316 is moved to the end of partitioned sector 324, followed by the ‘0’ block of missing bits 326 from the first half 314, then the ‘1’ block of missing bits 328 from the second half 316, etc. The missing hits may be drawn from the detector domain 302 to the partitioned sector 324 in other manners, based on how real data (e.g., 306) is laid out in the detector domain 302 as it is received by the interleaver, in order that the missing bits are grouped by circulants in the partitioned sector 324.

Again, the diagram 300 is not drawn to scale, and the arrows indicating the general partitioning of the 12 user samples 310 to the X-bit long segments (e.g., 318, 320, 322) in the partitioned sector 324 is meant as a general and non-limiting illustration of one example of partitioning. The interleaver may be adapted to partition real data in any manner that groups missing bits.

Each of the X-bit long segments (e.g., 318, 320, 322) in the partitioned sector 324 are then interleaved in local interleaving processes (e.g., 330, 332, up to 334). The local interleaving is a quasi-random permutation of bits within the X-bit long segment (e.g., 318, 320, 322). In some embodiments, each of the local interleaving processes (e.g., 330, 332, up to 334) applies a different permutation, shuffling the bits differently in each X-bit long segment (e.g., 318, 320, 322). The local interleaving processes (e.g., 330, 332, up to 334) may be implemented in any of a variety of different hardware circuits, and may be performed serially or in parallel. For example, in some embodiments, the local interleaving processes (e.g., 330, 332, up to 334) are implemented serially using a scratch pad memory, a read-only memory (ROM) containing the permutation for each of the X-bit long segments (e.g., 318, 320, 322), and selectors such as multiplexers to place each bit where directed by the permutation in the ROM.

Notably, the missing bits in the partitioned sector 324 are already grouped into six circulants of X bits each, and local interleaving processes (e.g., 336, 338) are applied to any of the six circulants that contain any real data. Although all of the final six circulants in the partitioned sector 324 are illustrated with crosshatching to indicate missing bits, some or all of these six circulants may contain real data, depending on how much real data was contained in the particular sector received by the interleaver. As disclosed above, missing bits are grouped at the end of the sector, thus at the right end of the partitioned sector 324 in the diagram 300. For example, if the sector has Z missing bits, and X<z<2X, blocks 308 and 326 making up the last X-bit circulant in the partitioned sector 324 are completely void of real data, and block 328 from the second half 316 of the detector domain 302 is also missing bits. The local interleaving process 338 may be skipped, because it applies to the last circulant which contains no real data. The next-to-last interleaving process will not be skipped, because although it contains Z-X missing bits, it also contains 2X-Z real data bits. The interleaver is operable in some embodiments to fill the Z-X missing bits in the next-to-last circulant (or any circulant containing some real data and some missing bits) with fill data, such as ‘0’ values and corresponding maximum LLR confidence values.

The locally-interleaved real data 340 is divided into smaller chunks of data, for example into Y-bit chunks (e.g., 342, 344), which are permuted or moved in Y-bit chunks (e.g., 342, 344) in a global interleaving process 346, where Y<X and, in some embodiments, Y is an integer fraction of X, such as X/4. The global interleaving process 346 carries whole Y-bit chunks (e.g., 342, 344) across the block of known real data 348, interleaving chunk-wise in contrast to the bit-wise interleaving done in the local interleaving processes (e.g., 336, 338) which operate only across X-bit long segments (e.g., 318, 320, 322).

The global interleaving process 346 operates only across the circulants that always contain real data 348, and do not operate on the last 6 circulants, whether they contain real data or not, to avoid shifting missing bits out of the last 6 circulant positions and into the circulants that should only contain real data 348. In some embodiments, another global interleaving process is performed across those of the last 6 circulants that are full of real data, to provide additional protection against burst errors for large sectors.

Performing both local and global interleaving increases the separation of burst errors, and also allows the local interleaving processes (e.g., 330, 332, up to 334) to start interleaving before the entire sector is received by the interleaver, reducing latency.

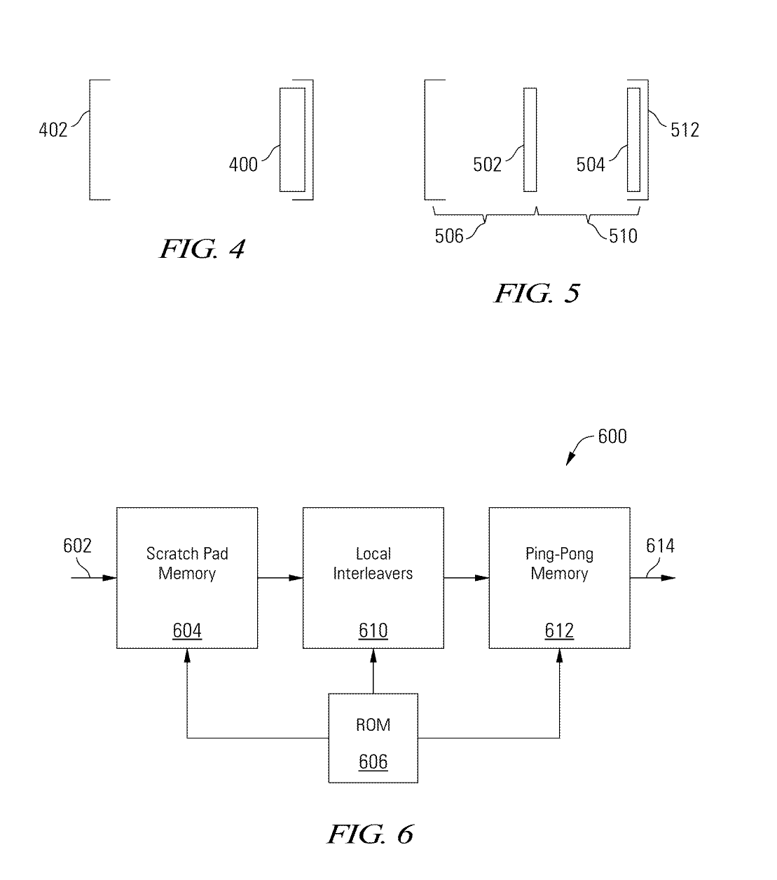

Turning to FIG. 4, skipping of circulants during local decoding iterations in a non-layer variable sector size LDPC decoder is enabled by concentrating missing bit positions in circulants 400 at the end of the H matrix 402. Variable node and check node calculations are performed iteratively column by column in the H matrix 402, and columns of circulants 400 that do not contain user data, or which are filled with missing bit positions, are skipped or omitted from local decoding iterations in the LDPC decoder. Any circulants containing some user data along with missing bit positions are included in the local decoding iterations.

The variable sector size decoding is also applicable to LDPC layer decoders. In some embodiments, the variable sector size LDPC layer decoder processes two circulants in parallel. To enable skipping of circulants during local decoding iterations in a variable sector size LDPC layer decoder, missing bit positions are concentrated as illustrated in FIG. 5 in circulants 502 and 504 at the ends of the first and second halves 506 and 510, respectively, of the H matrix 512. Variable node and check node calculations are performed iteratively column by column in the H matrix 512, with each of the parallel paths in the LDPC layer decoder processing circulants from separate halves 506 and 510 of the H matrix 512. If missing bits are concentrated equally in the circulants 502 and 504, both circulants 502 and 504 with no user data bits are omitted from local decoding iterations, saving the clock cycle in which the two circulants 502 and 504 would otherwise have been processed as well as reducing the possibility of oscillator and other errors. In the cases where one (e.g., 502) of the two circulants 502 and 504 does contain some user data while the other (e.g., 504) does not, the circulant 502 containing some user data is included in the local decoding iterations, and the circulant 504 with no user data is skipped. Thus, although the clock cycle cannot be saved, the possibility of errors is reduced during local iterations. Notably, although only two circulants 502 and 504 with missing bits are illustrated, more than one circulant in each half 506 and 510 of the H matrix 512 may be either partially or completely missing user data bits, with missing user data bits concentrated as much as possible in full circulants starting from the ends of each half 506 and 510 of the H matrix 512.

In embodiments in which the interleaver is preparing the data for an LDPC layer decoder, the missing bits portion of the decoder domain 304 may include two or more sections adapted to contain circulants to be processed in parallel by the LDPC layer decoder. In these embodiments, the decoder domain 304 may contain, for example, two missing bit sections, one at the right end of the first half 314 of the sector and the other at the right end of the second half 316 of the sector, such that the circulants with missing bits are positioned in the H matrix as illustrated in FIG. 5.

Turning to FIG. 6, a block diagram of a variable sector size interleaver 600 is shown in accordance with various embodiments of the present invention. Data is received by the interleaver 600 at an input 602 and stored in a scratch pad memory 604. The sector partitioning may be performed as data is stored in the scratch pad 604, using a ROM 606 to control where data is stored in the scratch pad 604. (The term “partitioner” is used herein to refer to the scratch pad 604 and ROM 606 or to any other component that performs the partitioning of data disclosed above with respect to FIG. 3, in which real data and missing bits are separated.) Missing bit forcing may also be performed in the scratch pad 604, filling missing bit positions with ‘0’ values and corresponding maximum LLR confidence values. The data from the scratch pad 604 is interleaved in a number of local interleavers 610, with the permutations applied by each of the local interleavers 610 controlled by information stored in the ROM 606. Local interleaving may begin as soon as a segment to be locally interleaved is available in the scratch pad 604. As disclosed above, local interleaving may also be performed serially, with a single local interleaver performing the local interleaving for each X-bit segment of data, and applying a different permutation for each X-bit segment of data based on information in the ROM 606. The locally interleaved data from the local interleavers 610 is stored in a ping-pong memory 612 large enough to store an entire sector of data, or Nmax 350 (see FIG. 3). In some embodiment, ping-pong memory 612 is large enough to store two sectors of data, allowing the first portion of the ping-pong memory 612 to hold an interleaved sector for an LDPC decoder to decode while the second portion of the ping-pong memory 612 is being filled by the local interleavers 610. The global interleaving may be performed in the interleaver 600 by a memory mapping in the ROM 606, causing data to be read from the ping-pong memory 612 in an order which globally interleaves the output 614 as it is being read from the ping-pong memory 612 by the downstream LDPC decoder or other component.

Notably, the example embodiments disclosed herein are based on a local-global interleaver. However, the variable sector size interleaver is not limited to this topology and may comprise any type of interleaver.

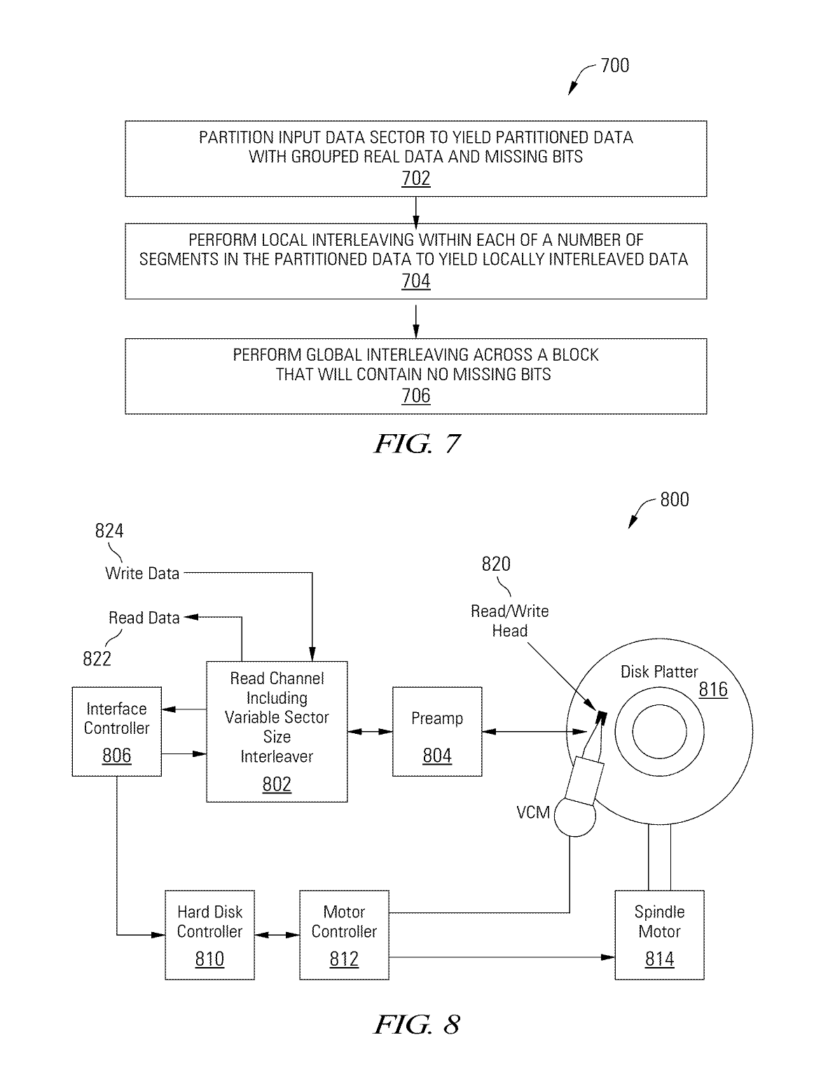

Turning to FIG. 7, a flow diagram 700 depicts a method for variable sector size interleaving in accordance with various embodiments of the present invention. The method of FIG. 7, or variations thereof, may be performed in interleaver circuits such as that illustrated in FIG. 6. Following flow diagram 700, the input data sector is partitioned to yield partitioned data with grouped real data and missing bits. (Block 702) Local interleaving is performed within each of a number of segments in the partitioned data to yield locally interleaved data. (Block 704) Each data segment may be permuted differently during the local interleaving as disclosed above. Circulants containing no real data may be skipped during local interleaving. Global interleaving is performed across a block that will contain no missing bits. (Block 706) Global interleaving can be performed chunk-wise or bit-wise. In some embodiments, an independent global interleaving process is performed on the block at the end of the sector that may contain missing bits, such as the last 6 circulants in the sector in the example embodiment disclosed above with respect to FIG. 3.

Although the interleaver disclosed herein is not limited to any particular application, several examples of applications are presented herein that benefit from embodiments of the present invention. FIG. 8 shows a storage system 800 including a read channel circuit 802 with a variable sector size interleaver in accordance with some embodiments of the present invention. Storage system 800 may be, for example, a hard disk drive. Storage system 800 also includes a preamplifier 804, an interface controller 806, a hard disk controller 810, a motor controller 812, a spindle motor 814, a disk platter 816, and a read/write head assembly 820. Interface controller 806 controls addressing and timing of data to/from disk platter 816. The data on disk platter 816 consists of groups of magnetic signals that may be detected by read/write head assembly 820 when the assembly is properly positioned over disk platter 816. In one embodiment, disk platter 816 includes magnetic signals recorded in accordance with either a longitudinal or a perpendicular recording scheme.

In a typical read operation, read/write head assembly 820 is accurately positioned by motor controller 812 over a desired data track on disk platter 816. Motor controller 812 both positions read/write head assembly 820 in relation to disk platter 816 and drives spindle motor 814 by moving read/write head assembly 820 to the proper data track on disk platter 816 under the direction of hard disk controller 810. Spindle motor 814 spins disk platter 816 at a determined spin rate (RPMs). Once read/write head assembly 820 is positioned adjacent the proper data track, magnetic signals representing data on disk platter 816 are sensed by read/write head assembly 820 as disk platter 816 is rotated by spindle motor 814. The sensed magnetic signals are provided as a continuous, minute analog signal representative of the magnetic data on disk platter 816. This minute analog signal is transferred from read/write head assembly 820 to read channel circuit 802 via preamplifier 804. Preamplifier 804 is operable to amplify the minute analog signals accessed from disk platter 816. In turn, read channel circuit 802 decodes and digitizes the received analog signal to recreate the information originally written to disk platter 816. This data is provided as read data 822 to a receiving circuit. As the received information is processed, read channel circuit 802 interleaves the received signal using a variable sector size interleaver. Such a variable sector size interleaver may be implemented consistent with that disclosed above in relation to FIGS. 3-6. In some cases, the variable sector size interleaving may be done consistent with the flow diagram disclosed above in relation to FIG. 7. A write operation is substantially the opposite of the preceding read operation with write data 824 being provided to read channel circuit 802. This data is then encoded and written to disk platter 816. It should be noted that various functions or blocks of storage system 800 may be implemented in either software or firmware, while other functions or blocks are implemented in hardware.

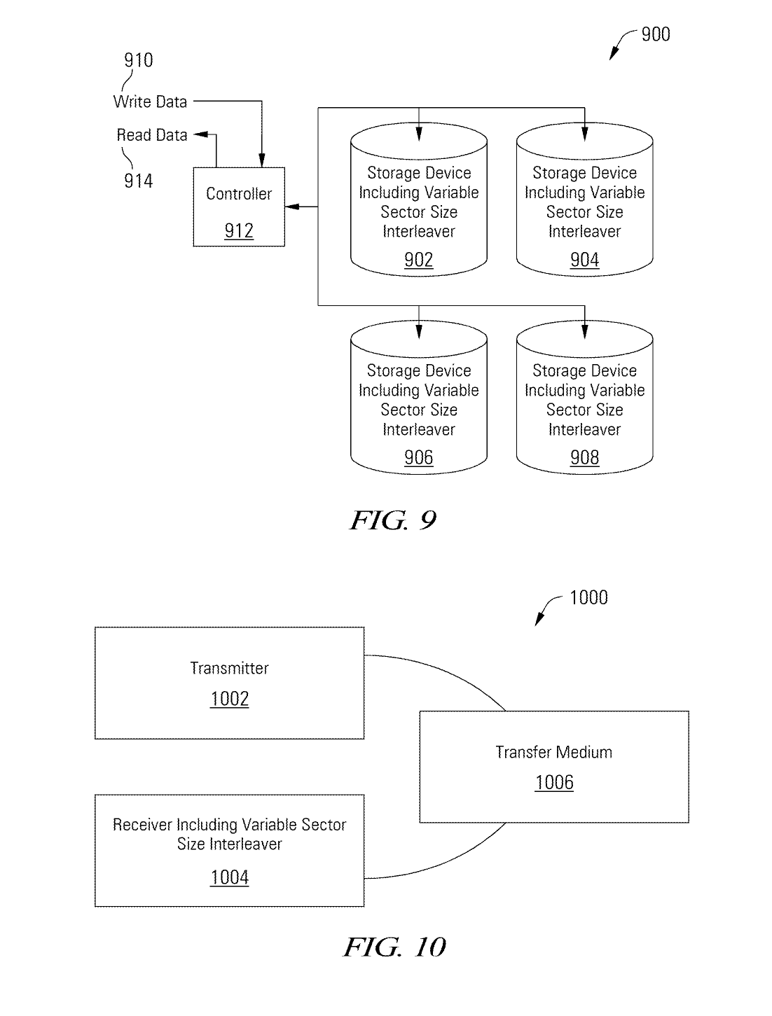

Turning to FIG. 9, a variable sector size interleaver may be integrated into a virtual storage system such as a RAID (redundant array of inexpensive disks or redundant array of independent disks) based storage system 900 that increases stability and reliability through redundancy, combining multiple disks as a logical unit. Data may be spread across a number of disks 902, 904, 906, 908 included in the RAID storage system 900 according to a variety of algorithms and accessed by an operating system as if it were a single disk. For example, data may be mirrored to multiple disks 902-908 in the RAID storage system 900, or may be sliced and distributed across multiple disks 902-908 in a number of techniques. If a small number of disks (e.g., 902) in the RAID storage system 900 fail or become unavailable, error correction techniques may be used to recreate the missing data based on the remaining portions of the data from the other disks (e.g., 904-908) in the RAID storage system 900. The disks 902-908 in the RAID storage system 900 may be, but are not limited to, individual storage systems such as that disclosed above in relation to FIG. 8, and may be located in close proximity to each other or distributed more widely for increased security. In a write operation, write data 910 is provided to a controller 912, which stores the write data 910 across the disks 902-908, for example by mirroring or by striping the write data 910. In a read operation, the controller 912 retrieves the data from the disks 902-908, performing error correction using variable sector size interleaving in either or both the controller 912 and the disks 902-908 and recreating any missing data where possible. The controller 912 then yields the resulting read data 914 as if the RAID storage system 900 were a single disk.

Turning to FIG. 10, a wireless communication system 1000 or data transmission device including a receiver 1004 with a variable sector size interleaver is shown in accordance with some embodiments of the present invention. Communication system 1000 includes a transmitter 1002 that is operable to transmit encoded information via a transfer medium 1006 as is known in the art. The encoded data is received from transfer medium 1006 by receiver 1004. Receiver 1004 incorporates a variable sector size interleaver. Such a variable sector size interleaver may be implemented consistent with that disclosed above in relation to FIGS. 3-6. In some cases, the decoding may be done consistent with the flow diagram disclosed above in FIG. 7.

The variable sector size interleaver disclosed herein enables a downstream decoder to perform a smaller number of decoding processing cycles, leading to a larger number of local iterations performed for short sector sizes, improving performance. Smaller decoding delays are achieved by skipping circulants, enabling a larger number of global iterations to be performed for short sector sizes, again improving performance. Faster convergence and less reliability value oscillation is achieved during decoding, improving performance and reducing power usage, as enabled by the variable sector size interleaver.

It should be noted that the various blocks discussed in the above application may be implemented in integrated circuits along with other functionality. Such integrated circuits may include all of the functions of a given block, system or circuit, or only a subset of the block, system or circuit. Further, elements of the blocks, systems or circuits may be implemented across multiple integrated circuits. Such integrated circuits may be any type of integrated circuit known in the art including, but are not limited to, a monolithic integrated circuit, a flip chip integrated circuit, a multichip module integrated circuit, and/or a mixed signal integrated circuit. It should also be noted that various functions of the blocks, systems or circuits discussed herein may be implemented in either software or firmware. In some such cases, the entire system, block or circuit may be implemented using its software or firmware equivalent. In other cases, the one part of a given system, block or circuit may be implemented in software or firmware, while other parts are implemented in hardware.

In conclusion, the present invention provides novel methods and apparatuses for variable sector size interleaving. While detailed descriptions of one or more embodiments of the invention have been given above, various alternatives, modifications, and equivalents will be apparent to those skilled in the art without varying from the spirit of the invention. Therefore, the above description should not be taken as limiting the scope of the invention, which is defined by the appended claims.

What is claimed is:

1. An apparatus for interleaving a variably sized block of data comprising:
a data partitioner operable to partition the block of data into a real data portion and a missing bits portion, wherein the real data portion is adapted to contain data bits from the variably sized block of data and wherein the missing bits portion is adapted to be filled with a variable number of the data bits;
at least one local interleaver operable to apply a permutation across each of a plurality of sub-portions of the real data portion and the missing bits portion; and
a global interleaver operable to apply a global permutation across the real data portion.

2. The apparatus of claim 1, wherein the variable number of the data bits comprises a range from none of the data bits to enough of the data bits to fill the missing bits portion.

3. The apparatus of claim 1, wherein the sub-portions of the missing bits portion correspond to circulants for an H matrix in a low density parity check decoder.

4. The apparatus of claim 1, wherein the missing bits portion comprises at least two sections adapted to contain circulants to be processed in parallel by a layered low density parity check decoder.

5. The apparatus of claim 1, wherein the at least one local interleaver is operable to apply a different permutation across each of the plurality of sub-portions.

6. The apparatus of claim 1, wherein the at least one local interleaver is operable to apply the permutation in bit-wise fashion.

7. The apparatus of claim 1, wherein the at least one local interleaver is operable to omit any of the sub-portions of the missing bits portion that do not contain any of the data bits.

8. The apparatus of claim 1, wherein the data partitioner is operable to force values for bits in any of the sub-portions of the missing bits portion that contain some of the data bits but which are not full of the data bits.

9. The apparatus of claim 1, wherein the global interleaver is operable to apply the global permutation in a data chunk-wise fashion, moving data chunks within the real data portion, wherein the data chunks each comprise a plurality of the data bits.

10. The apparatus of claim 1, wherein the global interleaver comprises a memory mapping.

11. The apparatus of claim 1, further comprising a second global interleaver operable to apply a second global permutation across the missing bits portion.

12. The apparatus of claim 1, wherein the apparatus is implemented as an integrated circuit.

13. The apparatus of claim 1, wherein the apparatus is incorporated in a storage device.

14. The apparatus of claim 1, wherein the apparatus is incorporated in a storage system comprising a redundant array of independent disks.

15. The apparatus of claim 1, wherein the apparatus is incorporated in a data transmission device.

16. A method of interleaving a variably sized block of data, comprising:
partitioning the data to yield partitioned data with grouped real data and missing bits;
performing a plurality of local interleaving operations within the partitioned data; and
performing a global interleaving operations within a real data portion of the partitioned data.

17. The method of claim 16, wherein the partitioned data has a fixed data size independent of a size of the variably sized block of data.

18. The method of claim 16, wherein the partitioned data comprises a missing bit portion, wherein all of the missing bits are located in the missing bit portion, wherein the missing bit portion is divided into circulants in an H matrix for a low density parity check decoder, and wherein partitioning the data with grouped real data and missing bits enables the low density parity check decoder to skip decoding of any of the circulants which contain no data bits from the variably sized block of data.

19. The method of claim 18, wherein the missing bit portion comprises at least two sections adapted to contain the circulants to be processed in parallel by a layered low density parity check decoder.

20. A storage system comprising:
a storage medium maintaining a data set;
a write head operable to magnetically record the data set to the storage medium; and
an interleaver operable to perform interleaving of a variably sized block of data, comprising:
a data partitioner operable to partition the block of data into a real data portion and a missing bits portion, wherein the real data portion is adapted to contain data bits from the variably sized block of data and wherein the missing bits portion is adapted to be filled with a variable number of the data bits;
at least one local interleaver operable to apply a permutation across each of a plurality of sub-portions of the real data portion and the missing bits portion; and
a global interleaver operable to apply a global permutation across the real data portion.
